(19) United States
(12) Patent Application Publication
(10) Pub. No.: US 2025/0235972 A1
(43) Pub. Date: Jul. 24, 2025

(54) BRACKETS, BRACKET ASSEMBLIES, MACHINERY ARRANGEMENTS AND SEMICONDUCTOR PROCESSING SYSTEMS INCLUDING BRACKETS AND BRACKET ASSEMBLIES, AND METHODS OF MAKING BRACKET ASSEMBLIES

(71) Applicant: ASM IP Holding B.V., Almere (NL)

(72) Inventors: Fan Gao, Chandler, AZ (US); Jingxuan Lyu, Chandler, AZ (US); William McCullough, Mesa, AZ (US); Partha Sarathy Reddy Kudala, Tempe, AZ (US)

(21) Appl. No.: 19/022,192

(22) Filed: Jan. 15, 2025

Related U.S. Application Data
(60) Provisional application No. 63/622,286, filed on Jan. 18, 2024.

(51) Int. Cl. B23Q 11/00; F16M 13/02

(52) U.S. Cl. CPC B23Q 11/0078; F16M 13/02

(57) ABSTRACT

A bracket includes a bracket with a seat portion, a first and second slotted portion, and a flange portion. The seat portion defines a bracket axis. The first slotted portion and the second slotted portion are laterally offset from the seat portion of the bracket body. The second slotted portion is further axially separated from the first slotted portion by the seat portion of the bracket body. The flange portion of the bracket body extends laterally the seat portion of the bracket body in a direction opposite the first slotted portion and the second slotted portion of the bracket body. The flange portion of the bracket body further extends in parallel with the bracket axis to constrain yaw angle of an interlock switch seated on the bracket body to the bracket axis. Bracket assemblies, machinery arrangements, semiconductor processing systems, and related methods of making bracket assemblies are also described.

### CROSS-REFERENCE TO RELATED APPLICATION(S)

This application claims the benefit of U.S. Provisional Application 63/622,286 filed on Jan. 18, 2024, the entire contents of which are incorporated herein by reference.

### FIELD OF INVENTION

The present disclosure generally relates to fixing pieces parts within assemblies, and more particularly to brackets employed to secure piece parts in assemblies.

### BACKGROUND OF THE DISCLOSURE

Brackets are commonly employed to fix piece parts within larger assemblies, such as to support interlock switches used to protect personnel in proximity to potentially hazardous machinery. The bracket generally supports the interlock switch relative to an access panel or door such that, when the access panel is removed or the door opened, the machinery behind the access panel or door is inoperable. This typically limits risk to personnel that may be in proximity to potentially hazardous machinery during operation of the machinery.

In some installations the interlock switch may become displaced, limiting (or preventing) the interlock switch from appreciating position of the access panel or door. For example, when the interlock switch becomes loose due to vibration in the installation environment and/or is bumped, the interlock may prevent operation of the machinery notwithstanding the access panel being properly emplaced or the door closed. Such nuisance trip may unnecessarily preventing operation of the machinery and/or desensitize personnel to trip events.

Such systems and methods have generally been considered suitable for their intended purpose. However, there remains a need in the art for improved brackets, bracket assemblies, machinery arrangements including brackets and bracket assemblies, and methods of making bracket assemblies. The present disclosure provides a solution to this need.

### SUMMARY OF THE DISCLOSURE

A bracket is provided. The bracket includes bracket body with a seat portion, a first slotted portion, a second slotted portion, and a flange portion. The seat portion defines a bracket axis. The first slotted portion is laterally offset from the seat portion of the bracket body. The second slotted portion is also laterally offset from the seat portion and is axially separated from the first slotted portion by the seat portion of the bracket body. The flange portion of the bracket body extends laterally the seat portion of the bracket body in a direction opposite the first slotted portion and the second slotted portion of the bracket body. The flange portion of the bracket body further extends in parallel with the bracket axis to constrain yaw angle an interlock switch seated on the bracket body relative to the bracket axis.

In addition to one or more of the features described above, or as an alternative, further examples of the bracket may include that the flange portion is a first flange portion and the bracket body has a second flange portion. The second flange portion may be separated from the first flange portion by the bracket axis. The second flange portion may be substantially parallel to the first flange portion.

In addition to one or more of the features described above, or as an alternative, further examples of the bracket may include that the seat portion defines a seat fixation aperture therethrough. The seat fixation aperture may be is axially offset from the first flange portion and the second flange portion along the bracket axis.

In addition to one or more of the features described above, or as an alternative, further examples of the bracket may include that the first slotted portion defines a slot pair therethrough. Slots of the slot pair may be axially offset from the first flange portion and the second flange portion of the bracket body along the bracket axis. The slots of the first slot pair may be substantially orthogonal relative to the bracket axis defined by the seat portion of the bracket body.

In addition to one or more of the features described above, or as an alternative, further examples of the bracket may include a pin member fixed to the seat portion of the bracket body. The pin member may extend from the seat portion of the bracket body in a direction opposite both the first slotted portion and the second slotted portion of the bracket body.

In addition to one or more of the features described above, or as an alternative, further examples of the bracket may include that the pin member separates the flange portion from the bracket axis. The pin member may separate the second flange portion from the first flange portion.

In addition to one or more of the features described above, or as an alternative, further examples of the bracket may include that the pin member is a first pin member and that the bracket includes a second pin member. The second pin member may be fixed to the seat portion. The second pin member may extend from the seat portion in a direction opposite the first slotted portion and the second slotted portion of the bracket body. The second pin member may be separated from the first pin member by the bracket axis.

In addition to one or more of the features described above, or as an alternative, further examples of the bracket may include that the second slotted portion of the bracket body defines a singular slot therethrough. The singular slot may be substantially orthogonal relative to the bracket axis. The first slotted portion may define a slot pair therethrough and slots of the slot pair may be substantially orthogonal relative to the bracket axis.

In addition to one or more of the features described above, or as an alternative, further examples may include that the bracket body is formed from a metallic sheet material.

A bracket assembly is provided. The bracket assembly includes a bracket as described wherein the bracket body formed from a metallic sheet material. An interlock switch extends in parallel with the flange portion of the bracket body, an impaling fastener is seated in the seat portion of the bracket body and fixes the interlock switch to the seat portion of the bracket body, and a first pin member and a second pin member are seated in the seat portion of the bracket body and fix the interlock switch in yaw angle relative to the bracket axis.

In addition to one or more of the features described above, or as an alternative, further examples of the bracket assembly may include an interlock circuit lead with a bayonet connector fixed to the interlock switch. The bayonet connector may extend axially along the bracket axis and overly the first slotted portion of the bracket body.

In addition to one or more of the features described above, or as an alternative, further examples of the bracket assembly may include that the interlock switch has an interlock member receptacle. The interlock member receptable may overlay the seat portion of the bracket body. The bracket assembly further comprising an interlock member movably supported relative to the interlock switch and received within the interlock member receptacle.

In addition to one or more of the features described above, or as an alternative, further examples of the bracket assembly may include an interlock circuit electrically connected to the interlock switch. The interlock switch may be configured to be electrically open when an interlock member is displaced from an interlock member receptacle defined within a housing of the interlock switch.

In addition to one or more of the features described above, or as an alternative, further examples of the bracket assembly may include a locknut. The locknut may be captive between the impaling fastener and the seat portion of the bracket body. The bracket assembly may include a resilient member. The resilient member formed from an elastomeric material captive between the impaling fastener and the interlock switch.

A semiconductor processing system is provided. The semiconductor processing system includes an enclosure including a frame member and an access panel or door removably fixed to the relative to a frame member. A process module is arranged within the enclosure and a bracket as described above is fixed to the frame member of the enclosure. An interlock switch is arranged within the enclosure and fixed to the bracket and an interlock circuit is electrically connected to the interlock switch. The interlock switch is configured to electrically close the interlock circuit when the access panel or door is fixed to the frame member. The interlock switch is configured to electrically open the interlock circuit when the access panel or door is displaced from the frame.

A method of making a bracket assembly is provided. The method includes forming a bracket including a bracket body with a seat portion defining a bracket axis, a first slotted portion laterally offset from the seat portion of the bracket body, a second slotted portion laterally offset from the seat portion and axially separated from the first slotted portion by the seat portion of the bracket body, and a flange portion extending from the seat portion and in parallel to the bracket axis. An interlock switch is seated on the seat portion of the bracket body and yaw angle of the interlock switch relative to the bracket axis constrained with the flange portion of the bracket body.

In addition to one or more of the features described above, or as an alternative, further examples of the method may include connecting an interlock circuit lead to the interlock switch and fixing the bracket to a frame member of an enclosure, the enclosure housing machinery in a machinery arrangement. Forming the bracket may further include separating a natural frequency of the bracket assembly from an excitation frequency or excitation frequency range associated with operation of machinery housed within an enclosure containing a bracket member to which the bracket assembly is fastened.

In addition to one or more of the features described above, or as an alternative, further examples of the method may include fixing one or more pin member to the seat portion of the bracket body, slidably receiving the one or more pin member within the interlock switch, and further constraining the yaw angle of the interlock switch relative to the bracket axis using the one or more pin member.

In addition to one or more of the features described above, or as an alternative, further examples of the method may include that seating the interlock switch on the seat portion of the bracket body includes fastening the interlock switch to the seat portion of the bracket body with one or more vibration countermeasure structure.

In addition to one or more of the features described above, or as an alternative, further examples of the method may include that seating the interlock switch on the seat portion of the bracket body further includes (a) fixing a housing of the interlock switch to the seat portion of the bracket body in abutment with the flange portion of the bracket body, or (b) fixing the housing of the interlock switch to the seat portion of the bracket body such that the housing and the flange portion define a gap therebetween.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a machinery arrangement including a bracket assembly in accordance with the present disclosure, showing the bracket supporting an interlock switch relative to an access panel or door of an enclosure;

FIG. 2 is a side view of the bracket assembly of FIG. 1 according to an example of the present disclosure, showing an interlock switch assembled onto the bracket body adjacent to a flange portion of the bracket body and connected to an interlock circuit by a interlock circuit lead;

FIG. 3 is an exploded view of the bracket assembly of FIG. 1 according to an example of the present disclosure, showing the interlock switch and pin members of the bracket assembly exploded away from the bracket;

FIGS. 4 and 5 are perspective and plan views of a portion of the bracket assembly and the bracket assembly of FIG. 1 according to an example of the present disclosure, showing pin members and seating of the interlock switch relative to the flange portion of the bracket; and

FIGS. 6-8 are a block diagram of making the bracket assembly of FIG. 1 according to an example of the present disclosure, showing operations of the method according to an illustrative and non-limiting example of the method.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

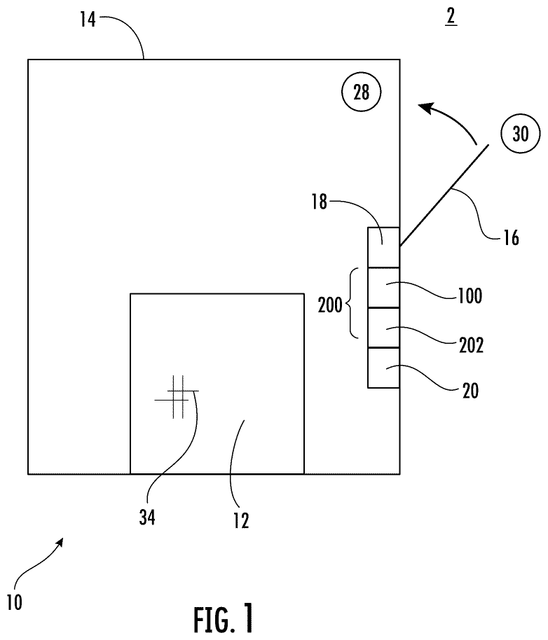

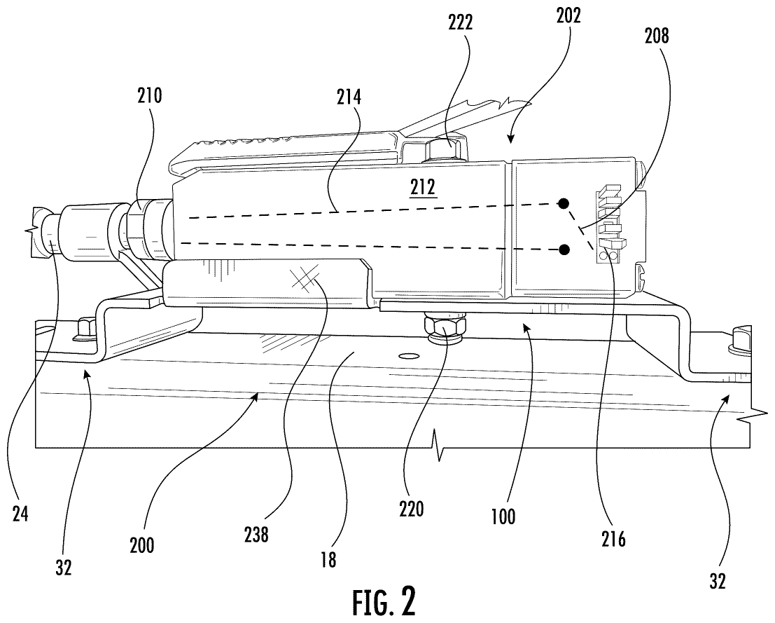

Reference will now be made to the drawings wherein like reference numerals identify similar structural features or aspects of the subject disclosure. For purposes of explanation and illustration, and not limitation, a partial view of an example of a machinery arrangement including a bracket assembly with a bracket in accordance with the present disclosure is shown in FIG. 1 and is designated generally by reference character 100. Other examples of brackets, bracket assemblies and machinery arrangements including bracket assemblies with brackets, and related methods of making bracket assemblies and machinery arrangements, or aspects thereof, are provided in FIGS. 2-8, as will be described. The systems and methods of the present disclosure may be used to support interlock switches relative to access panels and/or doors within enclosures housing machinery, such as in semiconductor processing systems that are potentially hazardous to personnel in proximity to the semiconductor processing system during operation, though the present disclosure is not limited to semiconductor processing systems or to supporting interlock switches in general.

Referring to FIG. 1, a machinery arrangement 10 is shown. The machinery arrangement 10 includes machinery 12, an enclosure 14 with an access panel or door 16, and a bracket assembly 200 including the bracket 100. The machinery 12 is housed within the enclosure 14, is separated from an external environment 2 outside of the enclosure 14 by the enclosure 14, and is accessible from the external environment 2 by remove (or opening) of the access panel or door 16. The access panel or door 16 is removably fixed to a frame member 18 of the enclosure 14 and is configured for removal from or displacement relative to a frame member 18 of the enclosure 14 supporting the access panel or door 16. The bracket assembly 200 includes an interlock switch 202 seated on the bracket 100 and is coupled therethrough to the enclosure 14. It is contemplated that the interlock switch 202 cooperate with an interlock circuit 20 to prevent (or cease) operation of the machinery 12 upon removal (or opening) of the access panel or door 16 from the enclosure 14. In certain examples the machinery arrangement 10 may include a semiconductor processing system. In such examples the machinery 12 may include one or more of a substrate handling robot and/or a process module. Examples of process modules include process configured for material layer deposition, etching, polishing, and lithography.

With reference to FIG. 2, the bracket assembly 200 is shown. The bracket assembly 200 generally includes the bracket 100 and the interlock switch 202. The bracket 100 is configured to couple the interlock switch 202 to the enclosure 14 (shown in FIG. 1), for example through the frame member 18 supporting the access panel or door 16 (shown in FIG. 1). The interlock switch 202 is configured to safety interlock the access panel or door 16 when emplaced or in a closed position 28 relative to the frame member 18 and in this respect is electrically connected to the interlock circuit 20 (shown in FIG. 1) by an interlock circuit lead 24. Electrical connection may be through a connector 210, which may be a bayonet connector. The connector 210 may extend axially along a bracket axis defined by a bracket body 102 of the bracket 100. The connector 210 may further overlay a first slotted portion 108 of the bracket body 102.

It is contemplated that the interlock switch 202 be configured to receive therein an interlock member 26. The interlock member 26 may be carried by (or fixed relative to) the access panel or door 16 and received within the interlock switch 202 when the access panel or door 16 is in a closed position 30 (shown in FIG. 1), and in this respect defines an interlock member receptacle 216 therein configured to receive the interlock member therein when the access panel or door 16 is in the closed position 30. As will be appreciated by those of skill in the art in view of the present disclosure, other types of interlock switches such as electromagnetically and/or optically coupled interlock switches may be coupled to the enclosure 14 and remain within the scope of the present disclosure.

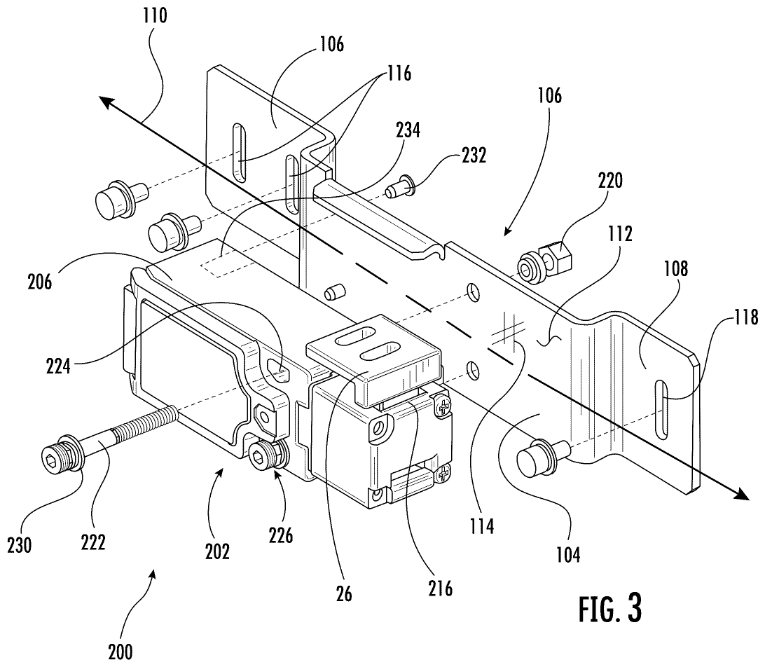

With reference to FIG. 3, the bracket assembly 200 is shown in an exploded view. The interlock switch 202 is configured to provide a signal indicative whether the access panel or door 16 (shown in FIG. 1) is removed or secured against the frame member 18 (shown in FIG. 1) and in this respect includes a housing 206, a switch circuit element 208 (shown in FIG. 2), and an electrical connector 210 (shown in FIG. 2). The switch circuit element 208 is arranged within an interior 212 (shown in FIG. 2) of the housing 206 and is coupled to the electrical connector 210 by a switch lead 214 (shown in FIG. 2), which is also arranged within the interior 212 of the housing 206. The electrical connector 210 is fixed to the housing 206, protrudes from an axial end face of the housing 206, and is configured to electrically couple the switch lead 214 to the interlock circuit lead 24 (shown in FIG. 2) and therethrough to the interlock circuit 20 (shown in FIG. 1). In this respect the electrical connector 210 may be threaded and/or include a bayonet-type feature to fix a corresponding connector of the interlock circuit lead 24 to the interlock switch 202.

The housing 206 of the interlock switch 202 defines an interlock member receptacle 216 within an exterior face of the housing 206. The interlock member receptacle 216 is configured to receive therein the interlock member 26. The interlock member 26 is in turn carried by the access panel or door 16 (shown in FIG. 1) and is movable relative to the frame member 18 with the access panel or door 16 between the access panel or door first position 28 (shown in FIG. 1) and the access panel or door second position 30 (shown in FIG. 1). It is contemplated that the interlock member 26 be received within the interlock member receptacle 216 when the access panel or door 16 is in the access panel or door first position first position 28, the interlock member 26 mechanically engaging the switch circuit element 208 (shown in FIG. 2) and electrically closing the interlock circuit 20 (shown in FIG. 1). It is also contemplated that the interlock member 26 disengage the switch circuit element 208 when the access panel or door 16 is displaced, for example when the access panel or door 16 is in the access panel or door second position 30, the interlock member 26 thereby being removed from the interlock member receptable 216 in such instances, the interlock circuit 20 thereby be electrically open. Examples of suitable interlock switches include Cadet™ 3 tongue-type interlock switches, available from Rockwell Automation, Inc. of Milwaukee, Wisconsin.

As will be appreciated by those of skill in the art in view of the present disclosure, the interlock circuit 20 may allow operation of the machinery 12 (shown in FIG. 1) when the switch circuit element 208 is electrically closed due to access panel or door 16 being seated on the enclosure 14 (shown in FIG. 1) when in the access panel or door first position 28, the machinery 12 thereby being in a safe condition for operation; and the interlock circuit 20 may not allow operation of the machinery 12 when the switch circuit element 208 is electrically open due to the access panel or door 16 having been moved to the access panel or door second position 30, such as when the machinery is undergoing service or maintenance, preventing operation of the machinery 12 from injuring personnel that may be in vicinity of the machinery 12 during service or maintenance events. As will also be appreciated by those of skill in the art in view of the present disclosure, displacement of the interlock switch 202 relative to the frame member 18 (shown in FIG. 1) may limit reliability of the interlock circuit 20 (shown in FIG. 1). For example, in some machinery arrangements, interlock switches may be displaced in the event bumped, such as during service or maintenance of the machinery housed within the enclosure protected by the interlock switch. Alternatively (or additionally), interlock switches may loosen, such as due to vibrational forces that may be characteristic of operation of certain types machinery, potentially causing the switch circuit element within the interlock switch to remain electrically open when an access panel or door is emplaced or closed. To avoid displacement, loosening, and/or to facilitate troubleshooting of the interlock switch 202 in the event of displacement and/or loosening, the bracket 100 is provided.

The bracket 100 includes a bracket body 102. The bracket body 102 is configured to fix the interlock switch 202 relative to the frame member 18 and in this respect has a seat portion 104 coupling a first slotted portion 106 to a second slotted portion 108. The seat portion 104 defines a bracket axis 110 and has a seating surface 112 that is substantially planar. The seating surface 112 is generally rectangular in shape and may be bisected by the bracket axis 110. It is contemplated that seat portion 104 of the bracket body 102 axially separate the first slotted portion 106 of the bracket body 102 from the second slotted portion 108 of the bracket body 102. In certain examples the bracket body 102 may be formed from a metallic sheet material 114. In this respect the bracket body 102 may formed from an aluminum-containing material, such as an aluminum alloy. Examples of suitable aluminum alloys include 5053 aluminum alloy. In further respect, the bracket body 102 may be formed from an iron-containing material, such as a stainless steel or carbon steel material. Examples of suitable stainless and carbon steel materials include 304 stainless and A36 steel alloy, which may be powder coated. Advantageously, forming the bracket body from the metallic sheet material 114 may simplify fabrication of the bracket 100, for example by enabling the bracket 100 to be formed using a stamping and/or pressing operation.

The first slotted portion 106 of the bracket body 102 is axially offset from the seat portion 104 along the bracket axis 110 and may be spaced apart from the bracket axis 110. The first slotted portion 106 may also be generally planer in shape and extend substantially in parallel with the bracket axis 110. In certain examples, the first slotted portion 106 may define a slot pair 116 therethrough. The slot pair 116 may include two slots each extending through a thickness of the bracket body 102 and extending laterally across a portion of a lateral width of the first slotted portion 106. The slots of the slot pair 116 may be axially spaced apart from one another along the bracket axis 110, substantially parallel to one another, and substantially orthogonal relative to the bracket axis 110. The second slotted portion 108 of the bracket body 102 may be similar to the first slotted portion 106 of the bracket body 102, additionally be axially separated from the first slotted portion 106 of the bracket body 102 by the seat portion 104 of the bracket body 102, and further define a singular slot 118 therethrough. The singular slot 118 may similarly extend through a thickness of the bracket body 102, extend laterally across a portion of the lateral width of the bracket body 102, and be substantially parallel to the slots of the slot pair 116.

It is contemplated that the slot pair 116 and the singular slot 118 be configured to receive therethrough a plurality of bracket-to-frame member fasteners 218. The frame member 18 (shown in FIG. 1) may define a first and second slotted portion fastener pattern 32 configured to threadedly receive therein the plurality of bracket-to-frame member fasteners 218. The first and second slotted portion fastener pattern 32 (shown in FIG. 2) may in turn include a plurality of threaded apertures conforming in position to axial positions of the slot pair 116 defined by the first slotted portion 106 of the bracket body 102. The first and second slotted portion fastener pattern 32 may further define a threaded aperture conforming spatially to the singular slot 118 of the second slotted portion 108 of the bracket body 102. As will be appreciated by those of skill in the art in view of the present disclosure, the slots of slot pair 116 and the singular slot 118 may cooperate to enable fixation of the bracket assembly 200 to the enclosure 14 (shown in FIG. 1), for example on the frame member 18, in a way that enables adjustment of the bracket assembly 200 relative to the enclosure 14 to accommodate variation within the form and fit of the access panel or door 16 (shown in FIG. 1). As will also be appreciated by those of skill in the art in view of the present disclosure, although shown and described herein as having three (3) slots, it is to be understood and appreciated that the bracket body 102 may have fewer or additional slots and remain within the scope of the present disclosure.

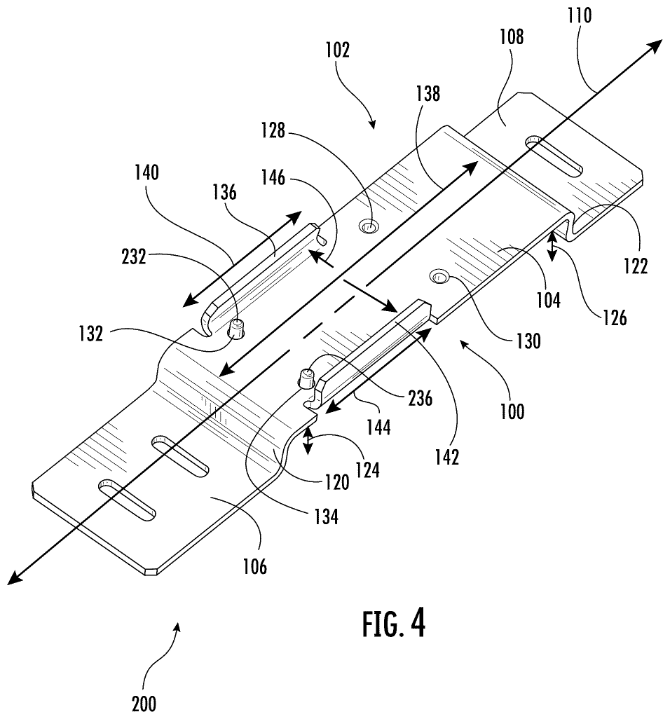

With reference to FIG. 4, the bracket body 102 may have a first intermediate portion 120 and a second intermediate portion 122. The first intermediate portion 120 is arranged axially between the first slotted portion 106 and the seat portion 104 of the bracket body 102, couples the first slotted portion 106 to the seat portion 104 of the bracket body 102, and defines a first seat offset 124 between the first slotted portion 106 and the seat portion 104 of the bracket body 102. The first intermediate portion 120 may be substantially orthogonal (at least in part) relative to the seat portion 104 of the bracket body 102. The first intermediate portion 120 may be oblique (at least in part) relative to the seat portion 104 of the bracket body 102. The second intermediate portion 122 may be similar to the first intermediate portion 120, additionally be axially separated from the first intermediate portion 120 along the bracket axis 110, and couple the seat portion 104 of the bracket body 102 to the second slotted portion 108 of the bracket body 102. It is contemplated that the second intermediate portion 122 define a second seat offset 126 between the second slotted portion 108 of the bracket body 102 and the seat portion 104 of the bracket body 102. It is further contemplated that the first seat offset 124 and the second seat offset 126 cooperate to space the seat portion 104 from the frame member 18 (shown in FIG. 1) by a distance sufficient to enable a nut 220 (shown in FIG. 2) to threadedly received on an impaling fastener 222 (shown in FIG. 2) to fix the interlock switch 202 (shown in FIG. 1) to the bracket member 18 for fixation of the bracket assembly 200 within the enclosure 14 (shown in FIG. 1). The nut 220 maybe captive between the impaling fastener 222 and the seat portion 104 of the bracket body 102.

In certain examples, the second seat offset 126 may be substantially equivalent to the first seat offset 124. In accordance with certain examples, the seat portion 104 of the bracket body 102 may be configured such that the interlock switch 202 (shown in FIG. 1) may be fixed to the bracket 100 by the impaling fastener 222 (shown in FIG. 2). In this respect it is contemplated that the housing 206 (shown in FIG. 2) of the interlock switch 202 define a housing fixation aperture 224 therethrough, that the seat portion 104 define a seat fixation aperture 128 therethrough, and that the impaling fastener 222 extend through the housing fixation aperture 224 and the seat fixation aperture 128 to fix the interlock switch 202 to the bracket 100. In the illustrated example the interlock switch 202 is fixed to the bracket 100 by two or more impaling fasteners. In this respect it is contemplated that the housing fixation aperture 224 be a first housing fixation aperture 224 and the housing 206 define a second housing fixation aperture 226 (shown in FIG. 3); that the seat fixation aperture 128 be a first seat fixation aperture 128 and the seat portion 104 of the bracket body 102 define a second seat fixation aperture 130; and that the impaling fastener 222 be a first impaling fastener 222 and the bracket assembly 200 further includes a second impaling fastener 228, the second impaling fastener 228 extending through the second housing fixation aperture 226 and the second seat fixation aperture 130 to fix the interlock switch 202 to the bracket 100.

In certain examples the nut 220 (shown in FIG. 2) may be a lock nut. As will be appreciated by those of skill in the art in view of the present disclosure, fixing the impaling fastener 222 in the bracket assembly 200 using lock nut may limit risk that the interlock switch 202 (shown in FIG. 1) become loose due to vibration associated with operation of the machinery 12 (shown in FIG. 1). In accordance with certain examples, a resilient member 230 (shown in FIG. 3) formed from an elastomeric material may be captive between the interlock switch 202 and the impaling fastener 222, such as an O-ring. As will also be appreciated by those of skill in the art in view of the present disclosure, the resilient member 230 may absorb vibration associated with operation of the machinery 12, also limiting risk that the interlock switch 202 loosen over time due to vibration communicated the bracket assembly 200, for example through the bracket member 18 (shown in FIG. 1) to which the bracket 100 is fastened. Advantageously, employment of either (or both) the locknut and the resilient member 230 as a vibration countermeasure devices may enable extending the interval between interlock switch inspections, improving availability and thereby throughput of the machinery arrangement 10 (shown in FIG. 1).

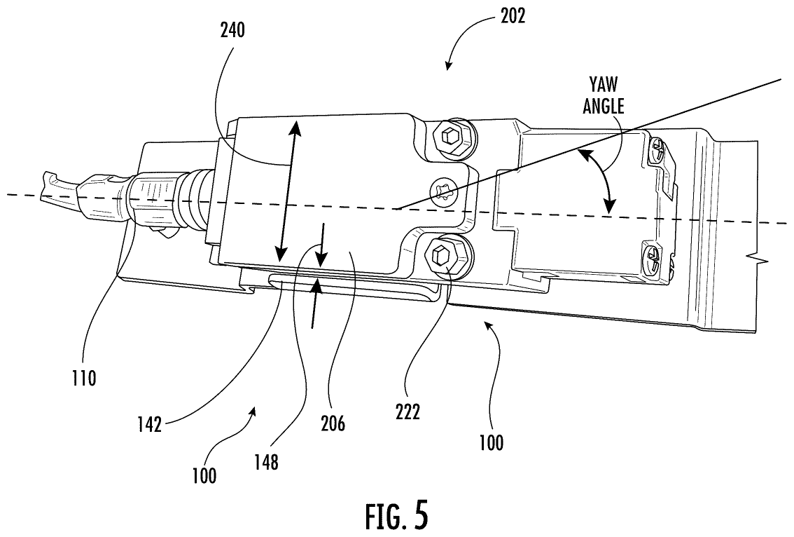

In certain examples, the bracket assembly 200 may include a pin member 232. In such examples the pin member 232 may be configured to fix the interlock switch 202 (shown in FIG. 1) on the seat portion 104 of the bracket body 102 in yaw angle (shown in FIG. 5) relative to the bracket axis 110. In this respect the pin member 232 may extend through the seat portion 104 of the bracket body 102 at location whereat the pin member 232 axially separates the seat fixation aperture 128 from the first slotted portion 106 (or the second slotted portion 108) of the bracket body 102. In further respect, the pin member 232 may extend from the seat portion 104 of the bracket body 102 in a direction opposite the first slotted portion 106 and the second slotted portion 108 of the bracket body 102. It is contemplated that the pin member 232 be slidably received within a corresponding pin recess 234 (shown in FIG. 3) defined within a bracket-facing surface of the housing 206 (shown in FIG. 3) of the interlock switch 202 when the interlock switch 202 is seated on the bracket 100. In this respect the seat portion 104 of the bracket body 102 may define therethrough a pin member aperture 132, and the pin member 232 may be fixedly seated within the pin member aperture 132. Advantageously, the pin member 232 may resist displacement of the interlock switch 202 in the even the interlock switch 202 is bumped, such as during service or maintenance of the machinery arrangement 10 (shown in FIG. 1). The pin member 232 may also operate to maintain the yaw angle of the interlock switch 202 in the event that the fastener 220 loosens, also improving reliability of the machinery arrangement 10.

In certain examples of the present disclosure the pin member 232 may be fixedly seated in the seat portion 104 of the bracket body 102 by a self-clinching arrangement. As will be appreciated by those of skill in the art in view of the present disclosure, self-clinching arrangements may simplify fabrication of the bracket assembly 200. For example, employment of a cinching arrangement may eliminate the need to form threads within the pin member aperture 132 defined by the seat portion 104 of the bracket body 102. Eliminating threads in turn enables forming the bracket body 102 from a relatively thin (or soft) metallic sheet material, limiting cost of the bracket 100 and/or the bracket assembly 200.

In certain examples the pin member 232 may be a first pin member 232 and the bracket 100 may include a second pin member 236. In such examples the second pin member 236 may be similar to the first pin member 232 and additionally protrude from the seat portion 104 of the bracket body 102 in a direction opposite the first slotted portion 106 and the second slotted portion 108 of the bracket body 102 at a location separated from the first pin member 232 by the bracket axis 110. In such examples the pin member aperture 132 may further be a first pin member aperture 132 and the seat portion 104 of the bracket body 102 may define a second pin member aperture 134. The second pin member aperture 134 may be similar to the first pin member aperture 132 and additionally separated from the first pin member aperture 132 by the bracket axis 110. It is contemplated that the second pin member aperture 134 and the first pin member aperture 132 may inhabit a common axial position along the bracket axis 110, though it is to be understood and appreciated that the second pin member aperture 134 may be axially offset from the first pin member aperture 132 and remain within the scope of the present disclosure. As will be appreciated by those of skill in the art in view of the present disclosure, the second pin member 236 may provide further resistance displacement of the interlock switch 202 in the even the interlock switch 202 is bumped and/or operate to maintain the yaw angle of the interlock switch 202 in the event that the fastener 220 loosens, further improving reliability of the machinery arrangement 10. Although shown and two (2) pin members, it is to be understood and appreciated that the bracket 100 may include a singular pin member or more than two (2) pin members and remain within the scope of the present disclosure.

Referring to FIG. 5 and with continuing reference to FIG. 4, it is contemplated that the bracket body 102 have a flange portion 136. The flange portion 136 may protrude from the seat portion 104 of the bracket body 102 in a direction opposite the first slotted portion 106 and the second slotted portion 108 of the bracket body 102. The flange portion 136 may extend axially along the bracket body 102, for example is a direction substantially parallel to the bracket axis 110. The flange portion 136 may further extend only partially along an axial length of the bracket body 102. In this respect the flange portion 136 may extend only partially along an axial length 138 of the seat portion 104 of the bracket body 102, the flange portion 136 having an axial length 140 that is less than an axial length 138 of the seat portion 104 of the bracket body 102. In certain examples the flange portion 136 of the bracket body 102 may be axially offset from the seat fixation aperture 128 along the bracket axis 110. In accordance with certain examples, the flange portion 136 may axially overlap the pin member 232. Advantageously, the flange portion 136 may operate as a countermeasure to change in the yaw angle (shown in FIG. 5) of the interlock switch 202 relative to the bracket axis 110 in event that the interlock switch 202 (shown in FIG. 1) is bumped and/or the impaling fastener 222 (shown in FIG. 3) becomes loose.

In certain examples, the flange portion 136 may be configured to shift a natural frequency 238 (shown in FIG. 2) of the bracket assembly 200 away from an excitation frequency or frequency range 34 (shown in FIG. 1) characteristic of operation the machinery arrangement 10 (shown in FIG. 1), the excitation frequencies within the environment containing the bracket assembly 200. For example, the machinery 12 (shown in FIG. 1) housed within the enclosure 14 (shown in FIG. 1) may include an excitation source. The excitation source may communicate excitation vibrational forces through the frame member 18 to the bracket assembly 200 with a frequency or frequency range 34 (shown in FIG. 1) characteristic of the machinery 12, due to rotational speed of a motor, potentially causing the bracket assembly 200 to ring (e.g., resonate such that relatively small vibratory forces are amplified) in the event that a natural frequency 238 (shown in FIG. 1) of the bracket assembly 200 is insufficient spaced from the frequency or frequency range 34 of the machinery 12. Shifting may be accomplished, for example, by one or more of height and length of the flange portion 136 in cooperation with stiffness of the metallic sheet material 114 (shown in FIG. 3) of the bracket body 102. As will be appreciated by those of skill in the art in view of the present disclosure, avoiding resonance response to excitation vibrations within the environment of the bracket assembly 200 can limit tendency of the interlock switch 202 to become loose during operation of the machinery 12, limiting (or eliminating) need to inspect and/or periodically tighten the impaling fastener 222 (shown in FIG. 3). Avoiding resonance may also enable the resilient member 230 (shown in FIG. 3) to absorb (dampen) residual vibrational forces, enabling the nut 220 to remain tight over prolonged service intervals, also limiting (or eliminating) need to inspect and/or periodically tighten the impaling fastener 222.

In certain examples the axial length 140 of the flange portion 136 may be between about 25% and about 75% of the axial length 138 of the seat portion 104 to accomplished the aforementioned natural frequency separation. In accordance with certain examples, the axial length 140 of the flange portion 136 may be between about 25% and about 60% of the axial length 138 of the seat portion 104, or between about 25% and about 50%, or even between about 25% and about 40% of the axial length 138 of the seat portion 104 of the bracket body 102. As will be appreciated by those of skill in the art in view of the present disclosure, other types of stiffening structures may be employed and remain within the scope of the present disclosure.

In certain examples the flange portion 136 may be a first flange portion 136 and the bracket body 102 may have a second flange portion 142. The second flange portion 142 may be similar to the first flange portion 136 and additionally be separated from the first flange portion 136 one or more of the bracket axis 110, the seat fixation aperture 128, and the pin member 232. In certain examples, the second flange portion 138 may axially overlap the first flange portion 136 of the bracket body 102 along the bracket axis 110, the first flange portion 136 and the second flange portion 142 inhabiting a common axial position along the bracket axis 110. It is contemplated that the second flange portion 142 may have an axial length 144 that is substantially equivalent to the axial length 140 of the first flange portion 136, and may overlap the first flange portion 136 along substantially the entirety of the axial length 140 of the first flange portion 136. As will be appreciated by those of skill in the art in view of the present disclosure, the second flange portion 142 may further constrain yaw angle of the interlock switch 202 relative to the bracket axis 110, the second flange portion 142 thereby also limiting displacement and/or change in yaw angle of the interlock switch 202 (shown in FIG. 1) in the event that the interlock switch 202 is bumped and/or the impaling fastener 222 becomes loose.

It is contemplated that the second flange portion 138 may be laterally separated from the first flange portion 136 by a separation distance 146. In certain examples, the separation distance 146 may be substantially equivalent to a lateral width 240 of the housing 206 of the interlock switch 202. In such examples the housing 206 may abut (e.g., be in intimate mechanical engagement) with the first flange portion 136 and/or the second flange portion 142 of the bracket body 102. As will be appreciated by those of skill in the art in view of the present disclosure, abutment of the housing 206 against either (or both) the first flange portion 136 and the second flange portion 142 may reduce (or prevent) displacement and/or change in yaw angle of the interlock switch 202 in event that the interlock switch 202 is bumped or the impaling fastener 222 becomes loose.

In certain examples, the separation distance 146 may be greater than the lateral width 240 of the housing 206 of the interlock switch 202. In such examples the either (or both) the first flange portion 136 and the second flange portion 142 may be separated from the housing 206 by a lateral gap 242. While also operating to limit displacement and/or change in yaw angle of the interlock switch 202 in the event the interlock switch 202 is bumped or the impaling fastener 222 becomes loose, the lateral gap 242 may further provide visual indication of whether the interlock switch 202 has been bumped and/or the impaling fastener 222 has become loose. Moreover, in examples where the lateral gap extends continuously along the axial length 140 of either (or both) the first flange portion 136 and the second flange portion 142, the lateral gap 242 may additionally provide tactile indication of whether the interlock switch 202 has been bumped and/or the impaling fastener 222 become loose. For example, a maintainer may assess position of the interlock switch 202 relative to the bracket 100 by running a feeler gauge through the lateral gap 242 and along the axial length thereof to ascertain whether the interlock switch 202 has displaced and/or whether the interlock switch 202 has changed in yaw angle relative to the bracket axis 110.

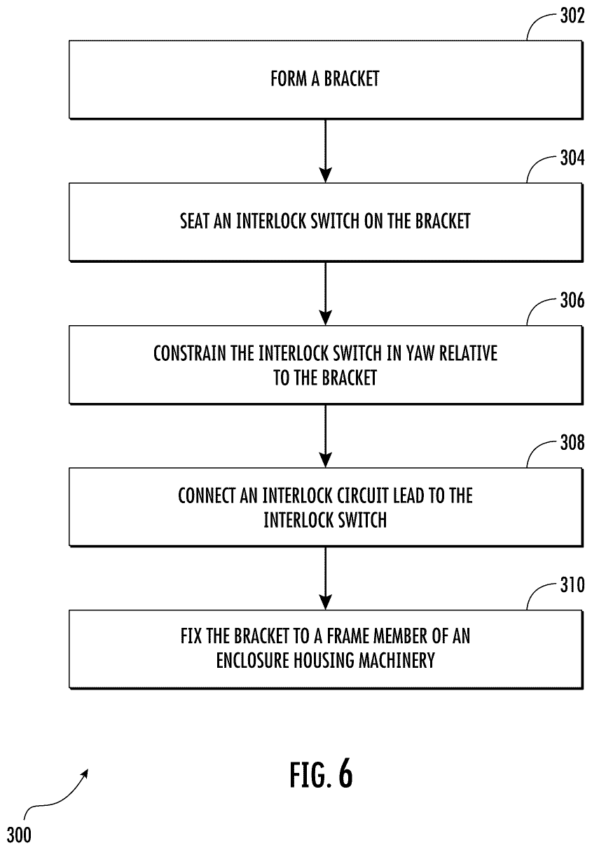

With reference to FIGS. 6-9, a method 300 of making a bracket assembly, e.g., the bracket assembly 200 (shown in FIG. 1), shown. As shown in FIG. 6, the method 300 includes forming a bracket, e.g., the bracket 100 (shown in FIG. 1), as shown with box 302. The method 300 also includes seating an interlock switch on a seat portion of a bracket body of the bracket, e.g., seating the interlock switch 202 (shown in FIG. 1) on the seat portion 104 (shown in FIG. 2) of the bracket body 102 (shown in FIG. 2), as shown with box 304. It is contemplated that the method 300 may further include constraining the interlock switch in yaw relative to a bracket axis defined by the seat portion of the bracket body, e.g., the bracket axis 110 (shown in FIG. 1), as shown with box 306. In certain examples the method 300 may additionally include connecting an interlock circuit lead to the interlock switch, e.g., the interlock circuit lead 24 (shown in FIG. 2), and fixing the bracket to a frame member of an enclosure housing machinery, e.g., to the frame member 18 (shown in FIG. 2), as shown with box 308 and box 310.

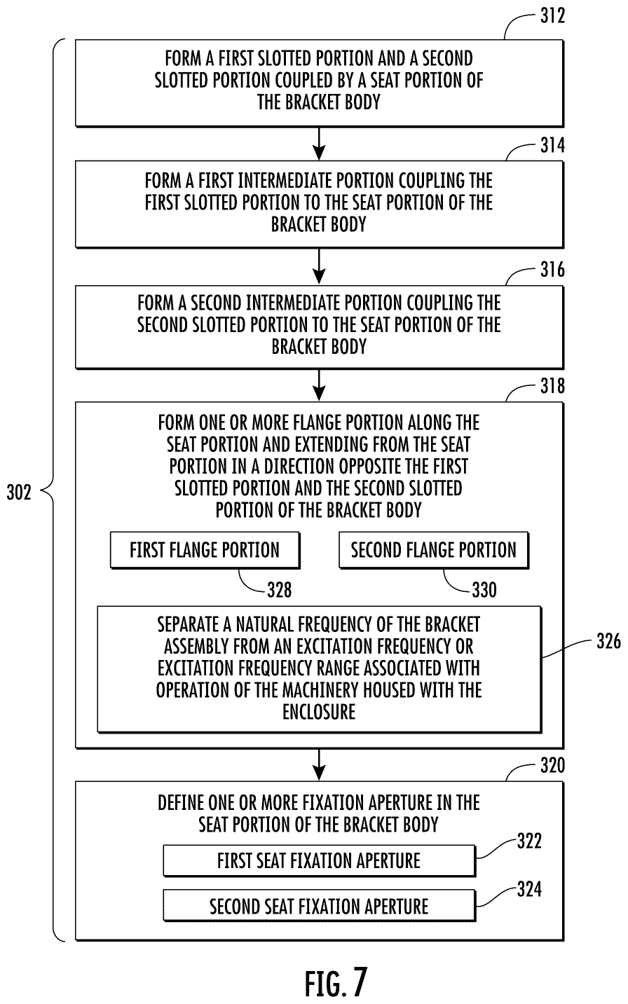

As shown in FIG. 7, forming 302 the bracket may include forming a first slotted portion and a second slotted portion coupled to one another by the seat portion of the bracket body, e.g., the first slotted portion 106 (shown in FIG. 2) and the second slotted portion 108 (shown in FIG. 2), as shown with box 312. Forming 302 the bracket may include forming a first intermediate portion coupling the first slotted portion to the seat portion, e.g., the first intermediate portion 120 (shown in FIG. 4), as shown with box 314. Forming the bracket 302 may include forming a second intermediate portion coupling the second slotted portion to the seat portion, e.g., the second intermediate portion 122 (shown in FIG. 4), as shown with box 316. Forming 302 the bracket may include forming one or more flange portion extending from the seat portion in a direction opposite the first slotted portion and the second slotted portion of the bracket body, e.g., either (or both) the first flange portion 136 (shown in FIG. 3) and the second flange portion 142 (shown in FIG. 3), as shown with box 318.

It is contemplated that the forming 302 the bracket body may include forming the bracket body from a metallic sheet material, e.g., the metallic sheet material 114 (shown in FIG. 3), as shown with bracket 302. It is also contemplated that forming 302 the bracket may include defining one or more seat fixation aperture in the seat portion of the bracket body, e.g., one or more of the first seat fixation aperture 128 (shown in FIG. 4) and the second seat fixation aperture 130 (shown in FIG. 4), as shown with box 320. In this respect forming the bracket may include defining the first seat fixation aperture and the second seat fixation aperture in the seat portion of the bracket body, as shown with box 322 and 324. In certain examples, forming 318 the one or more flange portion may include separating a natural frequency of the bracket assembly from an excitation frequency value or frequency range associated with operation of the machinery housed within the enclosure with the flange portion of the bracket body, e.g., separating the natural frequency 238 (shown in FIG. 1) of the bracket assembly from the excitation frequency or excitation frequency range 36 (shown in FIG. 1) communicated to the bracket assembly, as shown with box 326. Separating the natural frequency may be accomplished forming either (or both) the first flange portion and the second flange portion according to the excitation frequency or frequency range characteristic of the machinery and communicated to the interlock switch once installed, as shown with box 328 and box 330.

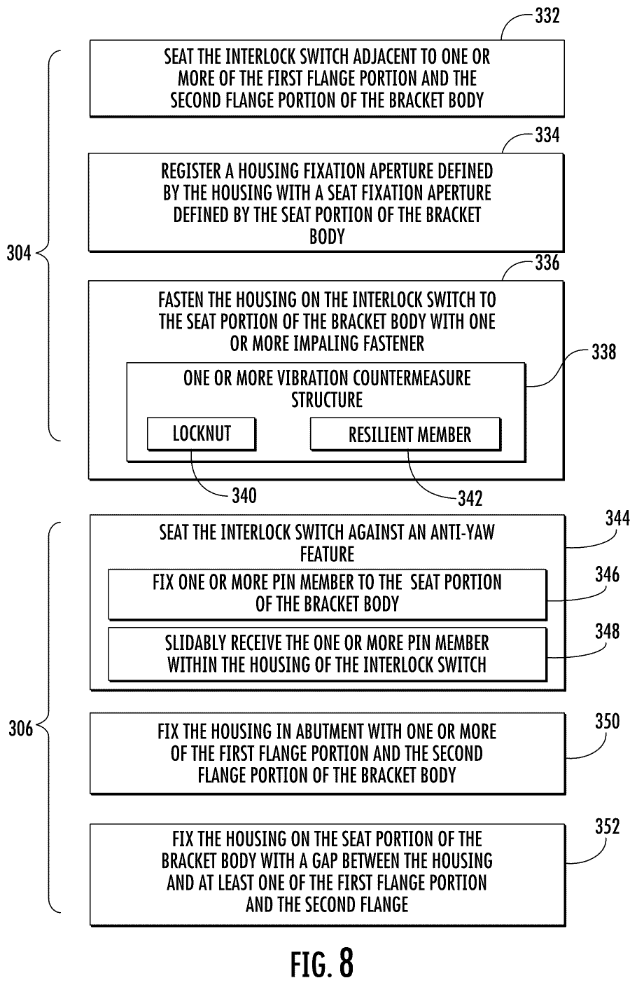

As shown in FIG. 8, seating 304 the interlock switch on the bracket may include seating the interlock switch adjacent to the one or more flange portion of the bracket body, for example between the first flange portion and the second flange portion of the bracket body, as shown with box 332. Seating 304 the interlock switch on bracket may include registering one or more housing fixation aperture to the one or more seat fixation aperture, e.g., one or more of the first housing fixation aperture 224 (shown in FIG. 3) and the second housing fixation aperture 226 (shown in FIG. 3) to the one or more seat fixation aperture, as shown with box 334. Seating 304 may include fastening the housing of the interlock switch to the seat portion of the bracket body using one or more impaling fastener, e.g., one or more of the first impaling fastener 222 (shown in FIG. 2) and the second impaling fastener 228 (shown in FIG. 2), as shown with box 336. In certain examples, fastening 328 the housing to the seat portion may include fastening the housing using a vibration countermeasure, as shown with box 338. For example, the respect the interlock switch may be fastened (and thereby secured) to the bracket using one or more locknut and/or a captive resilient member, as shown with box 340 and box 342.

In certain examples, seating 304 the interlock switch on the bracket may include seating the interlock switch against an anti-yaw feature, as shown with box 344. For example, one or more pin members may be fixed to the second portion of the bracket body, e.g., the first pin member 232 (shown in FIG. 4) and the second pin member 236 (shown in FIG. 4), and the one or more pin member slidably received within the housing body to limit yaw of the interlock switch relative to the bracket axis in the event that the interlock switch is bumped and/or in the event that the one or more impaling fastener loosens, as shown with box 346 and box 348. Alternatively (or additionally), the interlock switch may positioned such that the housing abuts either (or both) the first flange portion and the second flange portion of the bracket body to limit yaw of the interlock switch relative to the bracket axis in the event that the interlock switch is bumped and/or one or more of the impaling fasteners loosens, as shown with box 350. It is also contemplated that the interlock switch may be seated on the seat portion of the bracket body such that the housing is separated from one of the first flange portion and the second portion by a gap to provide visual and/or tactile indication that the interlock switch has been bumped and/or that the one or more impaling fastener has loosened, as shown with box 352.

Interlock switches are commonly employed to prevent operation of machinery in settings where operation of the machinery may present a hazard to personnel in proximity to machinery, generally through cooperation of with an interlock member carried by an access panel or door. The interlock member typically electrically closes a switch circuit element arranged with a housing of the interlock circuit when the access panel is emplaced on an enclosure housing the machinery or a door is closed, the interlock switch thereby enabling operation of the machinery housed within the enclosure. When the access panel is removed, or the door opened, the interlock member typically causes the switch circuit element to become electrically open, the machinery housed within the enclosure thereby ceasing operation and/or being prevented from resumption of operation. While generally suitable for their intended purpose, such interlock switches may sometimes become unreliable during operation of the machinery safeguarded by the interlock switch, such as in the event that fasteners fixing the interlock switch to the enclosure become loose due to vibration communicated to the interlock switch and/or in the event that the interlock switch is bumped, such as by a maintainer or personnel servicing the machinery. Once displaced the interlock may prevent operation of the machinery notwithstanding presence of the safeguarded access panel or the safeguarded door being closed, limiting throughput of the machinery housed within the enclosure safeguarded by the interlock switch.

In examples described herein interlock switches are mounted on brackets including flange portion. The flange portion extending along the interlock switch, limiting change in yaw angle of the interlock switch relative to the bracket in the event that fasteners securing the interlock switch to the bracket loose, and may further provide visual or tactile indication of whether the interlock switch has become loose. In certain examples the flange portions may cooperate with one or pin member fixed to the bracket and received within a housing of the interlock switch, one or more pin member further limiting yaw of the interlock switch relative to the bracket on which the interlock switch is seated. In accordance with certain examples, the flange portion may prevent ringing of the bracket assembly (and/or the limit switch) responsive to vibrational excitation that may accompany operation of the machinery housed within the enclosure, limiting (or eliminating) tendency of that natural frequency of the bracket assembly to encourage displacement of the interlock switch. It is also contemplated that the bracket assembly may include one or more vibration countermeasure structure, such as locknuts and/or o-rings, configured to prevent loosening of fasteners otherwise fixing the interlock switch to the bracket and/or absorbing vibration communicated to the bracket assembly through the frame member to which the bracket assembly is fixed.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A bracket, comprising:
a bracket body having:
a seat portion defining a bracket axis;
a first slotted portion laterally offset from the seat portion of the bracket body;
a second slotted portion laterally offset from the seat portion and axially separated from the first slotted portion by the seat portion of the bracket body; and
a flange portion extending from the seat portion of the bracket body in a direction opposite the first slotted portion and the second slotted portion, the flange portion further extending in parallel with the bracket axis to constrain yaw angle of an interlock switch seated on the bracket body relative to the bracket axis.

2. The bracket of claim 1, wherein the flange portion is a first flange portion and the bracket body has a second flange portion, the second flange portion separated from the first flange portion by the bracket axis, the second flange portion parallel to the first flange portion.

3. The bracket of claim 2, wherein the seat portion defines a seat fixation aperture therethrough that is axially offset from the first flange portion and the second flange portion.

4. The bracket of claim 2, wherein the first slotted portion defines a slot pair therethrough, slots of the slot pair axially offset from the first flange portion and the second flange portion of the bracket body, the slots of the slot pair further orthogonal relative to the bracket axis defined by the seat portion of the bracket body.

5. The bracket of claim 1, further comprising a pin member fixed to the seat portion and extending therefrom in a direction opposite the first slotted portion and the second slotted portion of the bracket body.

6. The bracket of claim 5, wherein the pin member separates the flange portion from the bracket axis.

7. The bracket of claim 6, wherein the pin member is a first pin member and further comprising a second pin member fixed to the seat portion and extending therefrom in the direction opposite the first slotted portion and the second slotted portion of the bracket body, the second pin member separated from the first pin member by the bracket axis.

8. The bracket of claim 1, wherein the second slotted portion defines a singular slot therethrough, the singular slot orthogonal relative to the bracket axis and wherein the seat portion defines a slot pair therethrough, the slot pair orthogonal relative to the bracket axis.

9. The bracket of claim 1, wherein the bracket body is formed from a metallic sheet material.

10. A bracket assembly, comprising:
a bracket as recited in claim 1, the bracket body formed from a metallic sheet material;
an interlock switch extending in parallel with the flange portion of the bracket body;
an impaling fastener seated in the seat portion of the bracket body and fixing the interlock switch to the seat portion of the bracket body; and
a first pin member and a second pin member seated in the seat portion of the bracket body and fixing the interlock switch in yaw angle relative to the bracket axis.

11. The bracket assembly of claim 10, further comprising an interlock circuit lead with a bayonet connector fixed to the interlock switch, the bayonet connector extending axially along the bracket axis and overlying the first slotted portion of the bracket body.

12. The bracket assembly of claim 10, wherein the interlock switch has an interlock member receptacle overlying the seat portion of the bracket body, and wherein the bracket assembly further comprising an interlock member movably supported relative to the interlock switch and received within the interlock member receptacle.

13. The bracket assembly of claim 10, further comprising an interlock circuit connected to the interlock switch, wherein the interlock switch is configured to be electrically open when an interlock member is displaced from an interlock member receptacle defined in the interlock switch.

14. The bracket assembly of claim 10, further comprising at least one of:
a locknut captive between the impaling fastener and the seat portion of the bracket body; and
a resilient member formed from an elastomeric material captive between the impaling fastener and the interlock switch.

15. A semiconductor processing system, comprising:
an enclosure including a frame member and an access panel or door removable fixed to the relative to the frame member;
a process module arranged within the enclosure;
a bracket as recited in claim 1 fixed to the frame member of the enclosure;
an interlock switch arranged within the enclosure and fixed to the bracket;
an interlock circuit connected to the interlock switch;
wherein the interlock switch is configured to electrically closed the interlock circuit when the access panel or door abuts the frame member; and
wherein the interlock switch is configured to electrically open the interlock circuit when the access panel or door is displaced from the frame member.

16. A method of making a bracket assembly, comprising:
forming a bracket including a bracket body with a seat portion defining a bracket axis, a first slotted portion laterally offset from the seat portion of the bracket body, a second slotted portion laterally offset from the seat portion and axially separated from the first slotted portion by the seat portion of the bracket body, and a flange portion extending from the seat portion and in parallel to the bracket axis;
seating an interlock switch on the seat portion of the bracket body; and
constraining yaw angle of the interlock switch relative to the bracket axis with the flange portion of the bracket body.

17. The method of claim 16, further comprising:
connecting an interlock circuit lead to the interlock switch;
fixing the bracket to a frame member of an enclosure, the enclosure housing machinery in a machinery arrangement; and
wherein forming the bracket comprises separating a natural frequency of the bracket assembly from an excitation frequency or excitation frequency range associated with operation of machinery housed within the enclosure.

18. The method of claim 16, further comprising:
fixing one or more pin member to the seat portion of the bracket body;
slidably receiving the one or more pin member within the interlock switch; and
further constraining the yaw angle of the interlock switch relative to the bracket axis using the one or more pin member.

19. The method of claim 16, wherein seating the interlock switch on the seat portion of the bracket body further comprises fastening the interlock switch to the seat portion of the bracket body with one or more vibration countermeasure structure.

20. The method of claim 16, wherein seating the interlock switch on the seat portion of the bracket body further comprises (a) fixing a housing of the interlock switch to the seat portion of the bracket body in abutment with the flange portion of the bracket body, or (b) fixing the housing of the interlock switch to the seat portion of the bracket body such that the housing and the flange portion define a gap therebetween.
